(19) United States
(12) Patent Application Publication
(10) Pub. No.: US 2005/0274766 A1
(43) Pub. Date: Dec. 15, 2005

(54) Back sack with heat dissipation effect

(75) Inventor: Sen-Mei Cheng, Changhua Hsien (TW)

Correspondence Address: TROXELL LAW OFFICE PLLC, SUITE 1404, 5205 LEESBURG PIKE, FALLS CHURCH, VA, 22041, US

(73) Assignee: Taiwan Paiho Limited

(21) Appl. No.: 10/885,620

(22) Filed: Jul. 8, 2004

(30) Foreign Application Priority Data
May 28, 2004 (CN) 093208457

(51) Int. Cl. A45F 3/04; H01L 23/34

(52) U.S. Cl. 224/644

(57) ABSTRACT

A back sack with a heat dissipation effect includes a sack pad mounted to a back abutment facet of a back sack thereon wherein the back pad is integrally made with a plurality of resilient areas, heat-dissipation areas, and buffer areas defining the top surface thereon, and the resilient areas and the heat-dissipation areas thereof are respectively provided with a plurality of support hoops and fleece rings of a preset height densely and neatly arranged at the surface thereon. The support hoops of the resilient areas are stood upright with vents defined therein and dividing passages formed at the adjacent sides thereof, and a coupling facet is disposed at the bottom side of the sack pad thereof. Thus, when a human back is abutted against the resilient areas of the sack pad, the support hoops with a better ventilating capability can flexibly sustain the back thereof, reducing the density of contact areas between the back and the back abutment facet of the back sack to cut down the friction there-between as well as stimulating blood circulation to provide a better massage effect. And, via the fleece rings made up of multi-yarn fabrics with absorptive capacity and tiny pores, the heat-dissipation areas thereof can serve to absorb moisture, transpire perspiration, and dissipate heat, etc., effectively avoiding the uncomfortable feeling of sticky stuffiness generated at the back thereof to maintain the hygiene of the back sack thereof.

### BACKGROUND OF THE INVENTION

The present invention is related to a back sack with a heat dissipation effect, including a sack pad mounted to a back abutment facet of a back sack thereon wherein the back pad is integrally made with a plurality of resilient areas, heat-dissipation areas, and buffer areas defining the upper surface thereon, and the resilient areas and the heat-dissipation areas thereof are respectively provided with a plurality of support hoops and fleece rings of a preset height densely and neatly arranged at the surface thereon. The support hoops of the resilient areas are stood upright with vents defined therein and dividing passages formed at the adjacent sides thereof; whereby, the sack pad is equipped with a better ventilating capability that can reduce the density of contact areas between a human back and the sack pad thereof so as to cut down the friction there-between. And, via the fleece rings made up of multi-yarn fabrics with absorptive capacity and tiny pores, the heat-dissipation areas thereof can serve to absorb moisture, transpire perspiration, and dissipate heat, effectively avoiding the uncomfortable feeling of sticky stuffiness generated at the back thereof to maintain the hygiene of the back sack thereof and boost the value of the back sack thereof.

Please refer to FIGS. 1 to 2 inclusive. A conventional back sack for mountaineering, traveling, or shopping comprises a back sack 10, 20 with a sack pad 11, 12 as shown in FIGS. 1, 2 wherein the sack pad 11, 12 is closely abutted against a human back, which tends to generate friction there-between according to the speed and weight of a user's steps in activities. The sack pad 11, 12 of the back sack 10, 20 is made up of either a rope net 111 or foamy cotton 211 with airy grooves defined thereon which, without any flexibility for massage effect thereof, can easily cause friction between the sack pad 11 and the back thereof due to the large contact areas there-between and result in uncomfortable feeling to the user. Although having some airy grooves for ventilating effect, the rope net 111 and the foamy cotton 211 are not equipped with the functions of moisture absorption, sweat transpiration, and heat dissipation, etc. Thus, perspiration generated tends to stick stuffily and uncomfortably at the back and the sack pad 11, 12 thereon, which, after a period of using time, can emit bad smell of sweat and mold, and destroy the cleanness and hygiene of the back sack 10, 20 thereof

### SUMMARY OF THE PRESENT INVENTION

It is, therefore, the primary purpose of the present invention to provide a back sack with a heat dissipation effect, including a sack pad mounted to a back abutment facet of a back sack thereon wherein the back pad has a plurality of resilient areas, heat-dissipation areas, and buffer areas defining the upper surface thereon, and the resilient areas and the heat-dissipation areas thereof are respectively provided with a plurality of support hoops and fleece rings of a preset height densely and neatly arranged at the surface thereon; whereby, in practical use, the support hoops of the resilient areas can flexibly sustain a human back abutted against thereon, isolating an airy space defined among the heat dissipation areas and the buffer areas thereof Besides, via vents formed at the support hoops therein and dividing passages defining every adjacent sides of the supporting hoops thereof, the sack pad is equipped with a better ventilating capability, which, in addition to providing a proper ventilating space there-between, can also reduce the density of contact areas between the back and the sack abutment facet of the back sack thereof, preventing the back from directly applying onto the back abutment facet of the back sack so as to cut down the uncomfortable feeling caused by the friction there-between for protection thereof.

It is, therefore, the second purpose of the present invention to provide a back sack with a heat dissipation effect wherein, via the fleece rings made up of multi-yarn fabrics with absorptive capacity and tiny pores, the heat-dissipation areas thereof can serve to absorb moisture, transpire perspiration, and dissipate heat, etc., effectively avoiding the uncomfortable feeling of sticky stuffiness generated at the back thereof to maintain the hygiene and boost the value of the back sack thereof.

It is, therefore, the third purpose of the present invention to provide a back sack with a heat dissipation effect wherein the resilient areas, the heat dissipation areas, and the buffer areas are alternatively interrelated with respect to one another in arrangement. Thus, when the back is abutted against the resilient areas of the sack pad, the support hoops thereof with proper hardness can flexibly sustain the back thereof, stimulating blood circulation and providing a better massage effect to achieve multiple effects of massage as well as ventilation and heat-dissipation to the back thereof.

It is, therefore, the fourth purpose of the present invention to provide a back sack with a heat dissipation effect wherein the sack pad thereof can also have bamboo charcoal contained therein, providing the sack pad with strong absorbing and decomposing capabilities as well as anti-bacteria, humid-adjustment, and deodorization power. Besides, far-infrared radiation proper for the absorption of human body is generated to speed up blood circulation and improve the health of human body, and healthy negative ions is increased in the air to balance the humidity inside the back sack and prevent bugs therein, efficiently promoting the quality of the back sack to achieve better deodorization and anti-bacteria effects.

### BRIEF DESCRIPTION OF THE DRAWINGS

FIG. 1 is a perspective view of a conventional back sack structure.

FIG. 2 is a perspective view of another conventional back sack structure.

FIG. 3 is a partially enlarged and perspective view of the present invention.

FIG. 4 is a perspective view of another embodiment of a sack pad of the present invention.

FIG. 5 is a perspective view of a third embodiment of the sack pad of the present invention.

FIG. 6 is a diagram showing the present invention mounted to a back sack thereon.

FIG. 7 is an enlarged and perspective view of a single support hoop of the present invention.

FIG. 8 is an enlarged and perspective view of a single fleece ring of the present invention.

FIG. 9 is a partially enlarged and perspective view of another embodiment of the present invention.

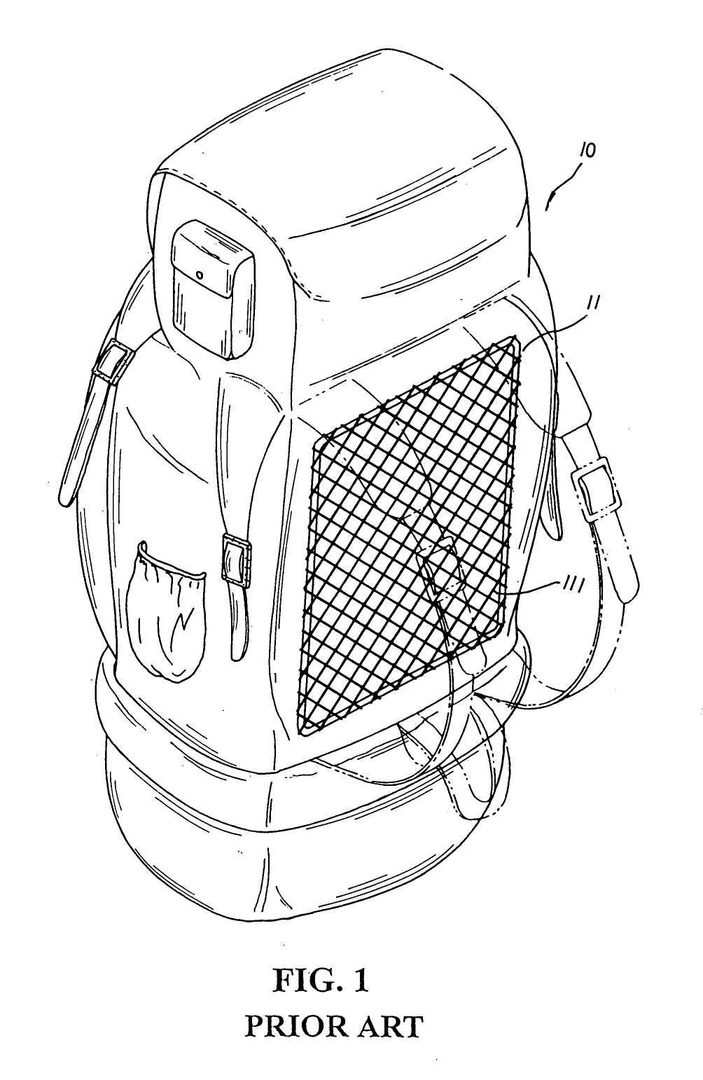

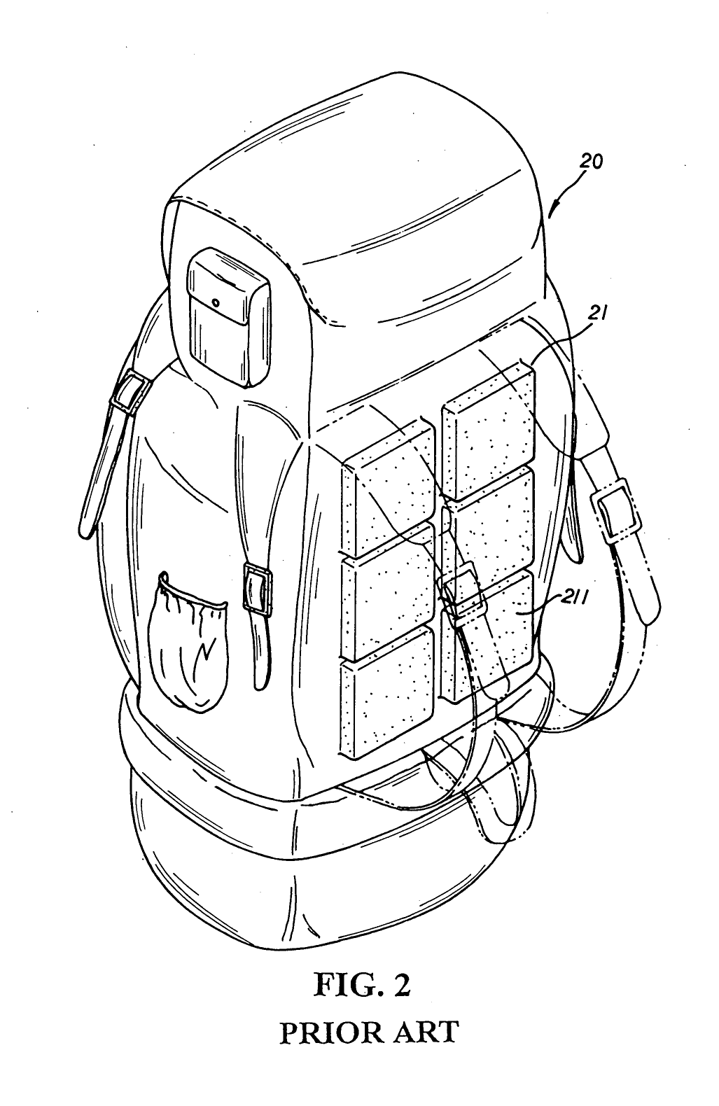

### DETAILED DESCRIPTION OF THE PREFERRED EMBODIMENTS

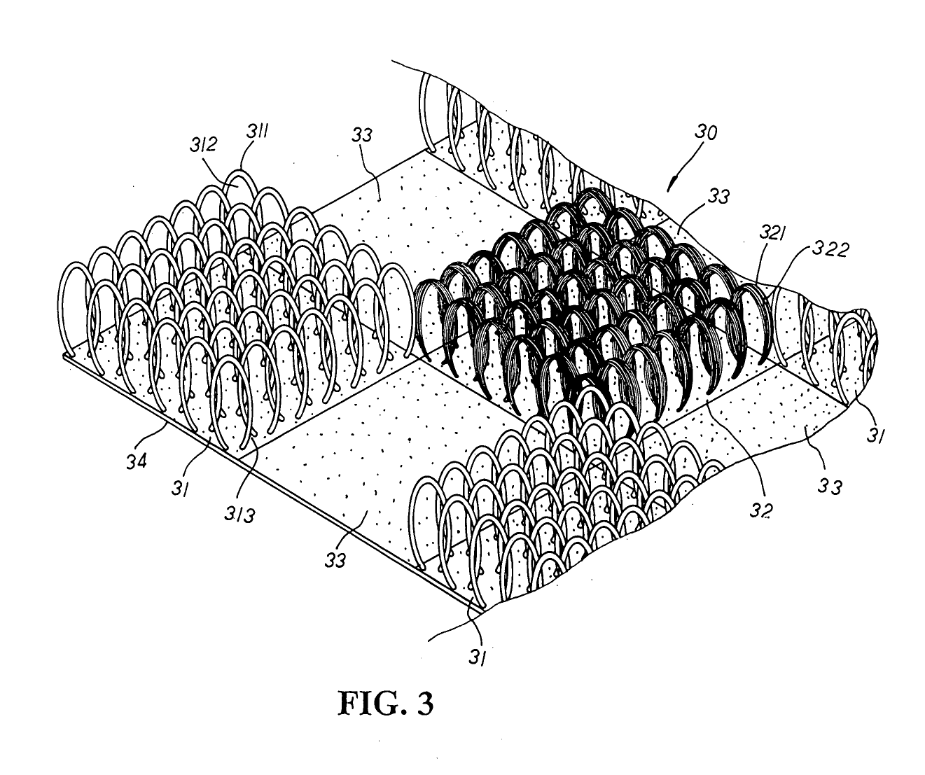

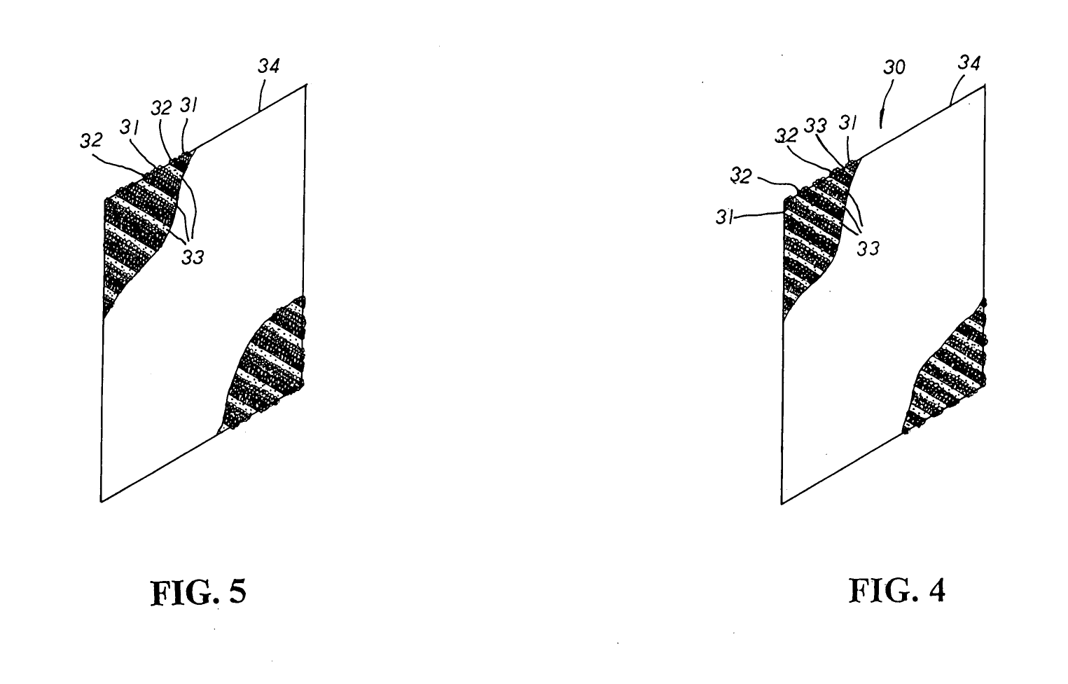

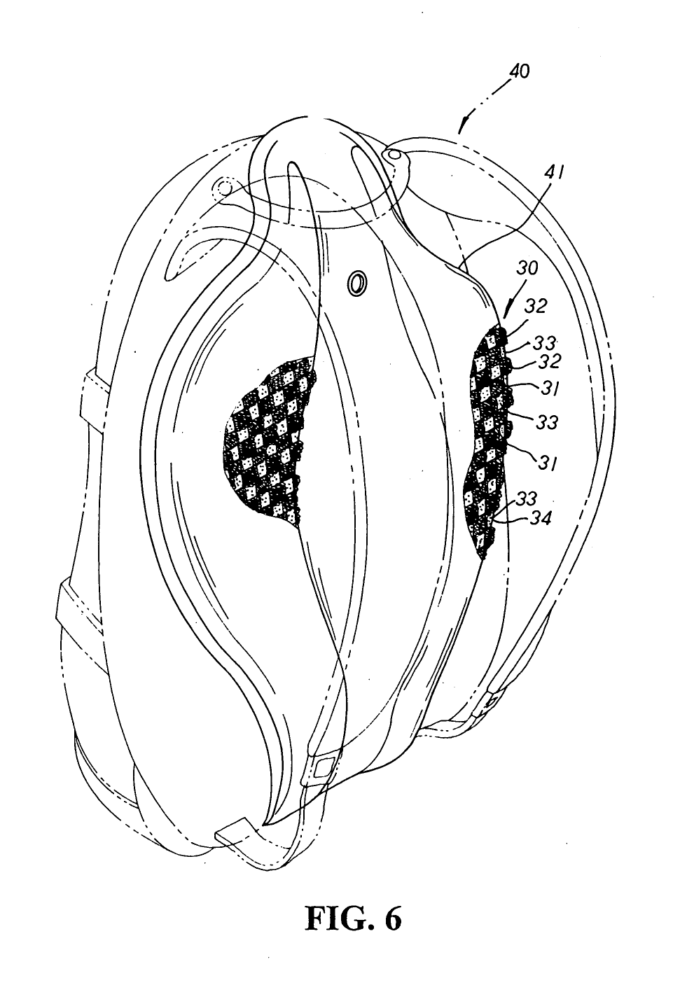

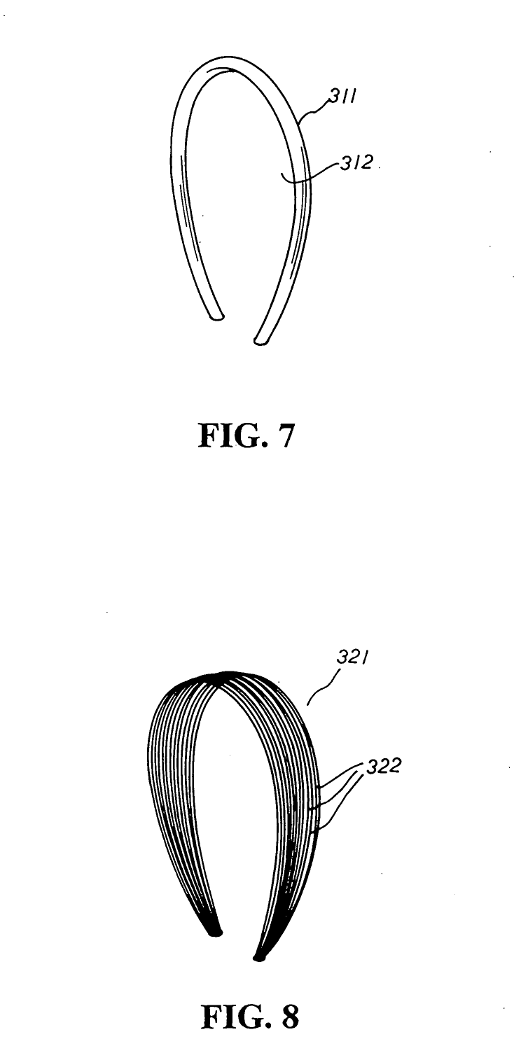

Please refer to FIGS. 3 to 8 inclusive. The present invention is related to a back sack with a heat dissipation effect, including a back pad 30 that, having bamboo charcoal contained therein, is integrally woven to form a plurality of resilient areas 31, heat-dissipation areas 32, and buffer areas 33 defining the top surface thereon. The resilient areas 31, heat-dissipation areas 32 and buffer areas 33 thereof can be made in any shapes such as rectangles or triangles as shown in FIG. 4, or oblique stripes as shown in FIG. 5, and are alternatively interrelated with respect to one another in regular or irregular arrangement thereof. The resilient areas 31 and the heat-dissipation areas 32 are respectively provided with a plurality of support hoops 311 and fleece rings 321 of a preset height densely and neatly arranged at the surface thereon. The support hoops 311 are stood upright in ring shapes with vents 312 defined therein and dividing passages 313 formed at the adjacent sides thereof A coupling facet 34 is disposed at the bottom side of the sack pad 30 thereof to be integrally combined with a binding article of EVA or PVC foam material (without shown in the diagram) via thermal-pressurized operation to generate heat welding thereof before mounted to a back abutment facet 41 of a back sack 40 of any styles such as a mountaineering backpack as shown in FIG. 6. The support hoops 311 of the resilient areas 31 as shown in FIG. 7 are made of stiff material like fibers with proper hardness for massage effect, and the fleece rings 321 of the heat-dissipation areas 32 as shown in FIG. 8 are made up of soft multi-yarn fabrics 322 with absorptive capability and tiny pores such as natural yarns, artificial yarns, moisture-absorptive and sweat-transpiring yarns, or irregular-section yarns, etc.

In practical use, the support hoops 311 of the resilient areas 31 and the fleece rings 321 of the heat-dissipation areas 32 thereof are alternatively interrelated to the buffer areas 33 of the sack pad 30 in arrangement. When a human back is mutually abutted against the resilient areas 31 of the sack pad 30, the support hoops 311 with proper hardness can flexibly sustain the back thereof, stimulating blood circulation and providing a better massage effect. Meanwhile, via the support hoops 311 thereof, the resilient areas 31 can prevent the back thereof from directly applying onto the back abutment facet 41 of the back sack 40, isolating an airy space defined among the buffer areas 33 and the heat-dissipation areas 32 thereof. And, via the vents 312 formed therein and the dividing passages 313 defining every adjacent sides thereof, the resilient areas 31 are thus equipped with a better ventilating capability, which, in addition to providing a proper ventilating space there-between, can also reduce the density of contact areas between the back and the sack pad 30 thereof and cut down the uncomfortable feeling caused by the friction thereof Via the fleece rings 321 made up of multi-yarn fabrics 322 with absorptive capability and tiny pores, the heat-dissipation areas 32 can also serve to absorb moisture, transpire perspiration, and dissipate heat, etc., effectively avoiding the sticky stuffiness generated at the back thereof so as to maintain the cleanness and hygiene of the back sack 40 thereof. Besides, via the bamboo charcoal contained therein, the sack pad 30 thereof is also equipped with strong absorbing and decomposing capabilities as well as anti-bacteria, humid-adjustment, and deodorization power. Far-infrared radiation proper for the absorption of human body can also be generated by the bamboo charcoal to speed up blood circulation and improve the health of human body, and healthy negative ions is increased in the air to balance the humidity inside the back sack 40 and prevent bugs therein, efficiently promoting the quality of the back sack 40 thereof to achieve better deodorization and anti-bacteria effects thereof.

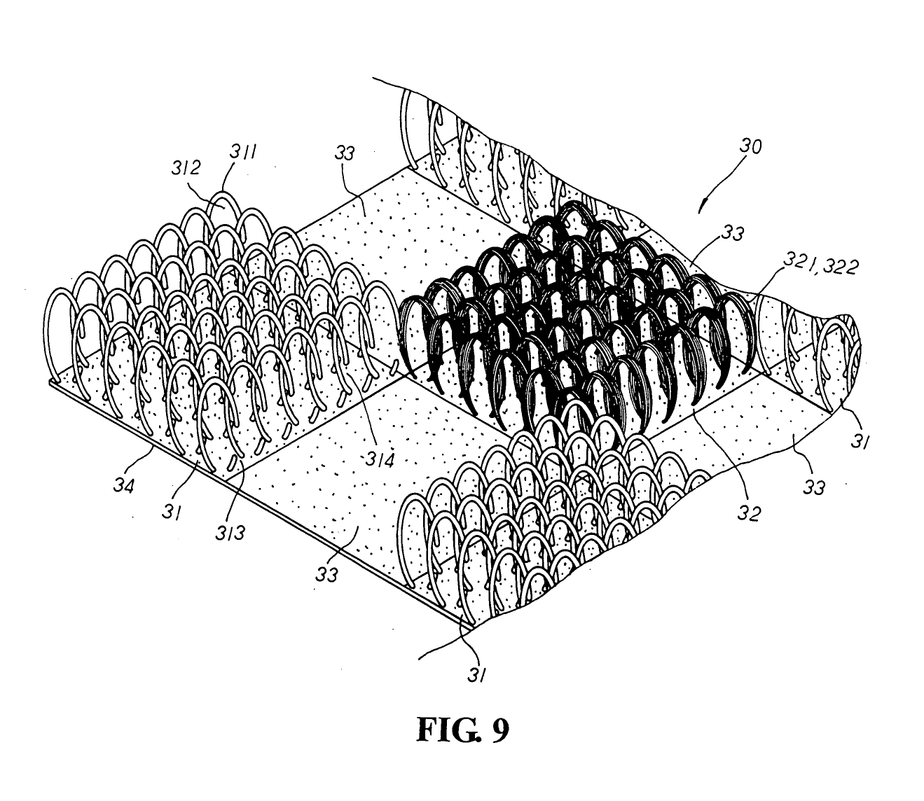

Please refer to FIG. 9. The support hoops 311 of the resilient areas 31 can also have openings 314 properly cut at preset spots thereon.

1. A back sack with a heat dissipation effect, including a back pad mounted to a back abutment facet of a back sack thereon wherein the back pad is integrally made with a plurality of resilient areas, heat-dissipation areas, and buffer areas defining the top surface thereon, and the resilient areas and the heat-dissipation areas thereof are respectively provided with a plurality of support hoops and fleece rings of a preset height densely and neatly arranged at the surface thereon; the support hoops of the resilient areas are stood upright in ring shapes with vents defined therein and dividing passages formed at the adjacent sides thereof, and a coupling facet is disposed at the bottom side of the sack pad thereof; thus, when a human back is abutted against the resilient areas of the sack pad, the support hoops with proper hardness can flexibly sustain the back thereof, reducing the density of contact areas between the back and the back abutment facet of the back sack for protection thereof as well as stimulating blood circulation to provide a better massage effect, and via the fleece rings made up of multi-yarn fabrics with absorptive capacity and tiny pores, the heat-dissipation areas can also serve to absorb moisture, transpire perspiration, and dissipate heat, etc., effectively avoiding the uncomfortable feeling of sticky stuffiness generated at the back thereof so as to maintain the cleanness and hygiene of the back sack thereof.

2. The back sack with heat dissipation effect as claimed in claim 1 wherein the resilient areas, the heat-dissipation areas and the buffer areas thereof can be formed in any shapes and arranged in regular or irregular manner.

3. The back sack with heat dissipation effect as claimed in claim 1 wherein the resilient areas, the heat-dissipation areas and the buffer areas thereof can be made in shapes like rectangles, triangles, or oblique stripes, etc.

4. The back sack with heat dissipation effect as claimed in claim 1 wherein the support hoops of the resilient areas can be made of stiff fiber material.

5. The back sack with heat dissipation effect as claimed in claim 1 wherein the fleece rings of the heat-dissipation areas can be made up of natural yarns, artificial yarns, moisture-absorptive and sweat-transpiring yarns, or irregular-section yarns, etc.

6. The back sack with heat dissipation effect as claimed in claim 1 wherein the sack pad can also have bamboo charcoal contained therein to provide the back sack thereof with deodorization and anti-bacteria effects thereof.

7. The back sack with heat dissipation effect as claimed in claim 1 wherein the support hoops of the resilient areas can also have openings properly cut at preset spots thereon.

8. The back sack with heat dissipation effect as claimed in claim 1 wherein the coupling facet of the sack pad is integrally combined with a binding article of EVA or PVC foam material via thermal-pressurized operation to generate heat welding thereof.
